(19) United States
(12) Patent Application Publication
(10) Pub. No.: US 2004/0080327 A1
(43) Pub. Date: Apr. 29, 2004

(54) Three poles monolithic quartz crystal filter measurement circuit and corresponding measuring method

(76) Inventor: Eric Wu, Tao-Yuan (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/279,798

(22) Filed: Oct. 25, 2002

(51) Int. Cl. H01L 41/04; H02N 2/00

(52) U.S. Cl. 324/727

(57) ABSTRACT

A measurement circuit and a corresponding method for a three poles monolithic quartz crystal filter. With the first and the second switch connected respectively to the first and the third pole, any terminal electrode of the filter (the second not included) is not only electrically coupled with the impedance matching circuits, but also electrically coupled with the terminal impeders or the measuring instruments according to the status of the switches. Therefore, by controlling the switches, Fo and BW of the filter could be acquired by the measuring instruments. Moreover, applying the conventional two-pole short-circuits bandwidth theorem, A-sym of the filter could also be acquired by separating the 3-poles filter into two 2-poles filter.

### BACKGROUND OF THE INVENTION

1. Field of the Invention

The invention relates to a measurement circuit and a corresponding method for a three poles monolithic quartz crystal filter, especially relates to the measurement circuit and the corresponding method for a three poles monolithic quartz crystal filter applying the two-pole short-circuits bandwidth theorem, on-off status of the switches, and the resistant-offset concept.

2. Description of the Prior Art

The three poles monolithic quartz crystal filter is often used in electronic units as a filter, for example, in analogous wireless communicative unit and digital wireless communicative unit.

Confined by the producing technology of the three poles monolithic quartz crystal filters, usually a three poles monolithic quartz crystal filter that has just been produced filters pass (or does not filter pass) the electromagnetic waves of a certain bandwidth that is close to Fo as the regulation requires (as is shown in FIG. 1A), but filters pass (or does not filter pass) some other electromagnetic waves of different bandwidth that is close to Fo (as is shown in FIG. 1B). The difference between the presumed frequency-filtering-wave relation and the real frequency-filtering relation is generally called anti-symmetry (abbr. as A-sym). The higher is the A-sym, the more different it is between the waveform of the permissible (or impermissible) filtration of the filter and the presumed waveform.

Obviously, in order to make sure that the property of the three poles monolithic quartz crystal filter is qualified for the regulation, the Fo, WB, and A-sym of the filter that has just produced have to be measured and adjusted (for example, the functioning voltage of each electrode).

However, in the prior technology, there are still two problems that have not been solved effectively in the technology of measuring the just-produced three poles monolithic quartz crystal filter:

(1) There is no simple and effective way of measuring the A-sym of the three poles monolithic quartz crystal filter. Although there has already been a simple, effective way of measuring the A-sym of two poles monolithic quartz crystal filter, which has only two electrodes, there is not a simple, effective way of measuring the three-poled filter. Although the S&A (Saunders) of U.S and NDK of Japan have already had products in the market, these products are quite complicated and inconvenient for the users.

(2) Measuring the Fo and the circuit of BW of a three poles monolithic quartz crystal filter is different from measuring the circuit of A-sym of a three poles monolithic quartz crystal filter. One main reason is that one is achieved through measuring the transparent response of the filter while the other is achieved through measuring the reflective response of the filter. Therefore, two circuits need to be used successively in order to measure the Fo, BW, and A-sym of a three poles monolithic quartz crystal filter, and thus the complicity of measuring process and the damage frequency of the filter are both heightened.

### SUMMARY OF THE INVENTION

The main purpose of the invention is to eliminate the common defects of the prior technology said above. The method and circuit of easily measuring the A-sym of a three poles monolithic quartz crystal filter are provided.

The invention comprises several main features as follows:

(1) A three poles monolithic quartz crystal filter is separated into two 2-poles filters by the process of terminal resistant offsetting the two electrodes on the two ends of the filter wave of the three poles monolithic quartz crystal filter.

(2) Applying the prior 2-pole short-circuits bandwidth theory by Robert Kingsman, 1986, the A-sym of the three poles monolithic quartz crystal filter, composed by the two 2-poles monolithic quartz crystal filters, can be achieved from the A-sym of the two 2-poles monolithic quartz crystal filters that share one same electrode.

(3) With the two electrodes on the two sides of the three poles monolithic quartz crystal filter electrically coupled with the switch, the electrodes can be electrically coupled with the terminal impedance (static capacitance that offsets the electrode) or the measuring instrument (that measures the Fo and BW) through the changing status of the switch. Therefore, the transparent response and the reflective response of the three poles monolithic quartz crystal filter can be acquired with these two electrodes through controlling the on and off status of the two switches.

### BRIEF DESCRIPTION OF THE DRAWINGS

A more complete appreciation and many of the attendant advantages will be readily obtained as the same becomes better understood by reference to the following detailed description when considered in connection with the accompanying drawings.

FIGS. 1A and 1B is the schematics of the fundamental constitution of a preferred embodiment of the invention and the relation of the waiting-to-be-measured three poles monolithic quarts crystal filter;

FIG. 2A is the process schematics of the second preferred embodiment of the invention;

FIG. 2B to FIG. 2D is the corresponding changes of the first preferred embodiment of the invention in the application of the second preferred embodiment of the invention; and

FIG. 2E is the schematics of the fundamental concept of the second preferred embodiment of the invention

### DESCRIPTION OF THE PREFERRED EMBODIMENT

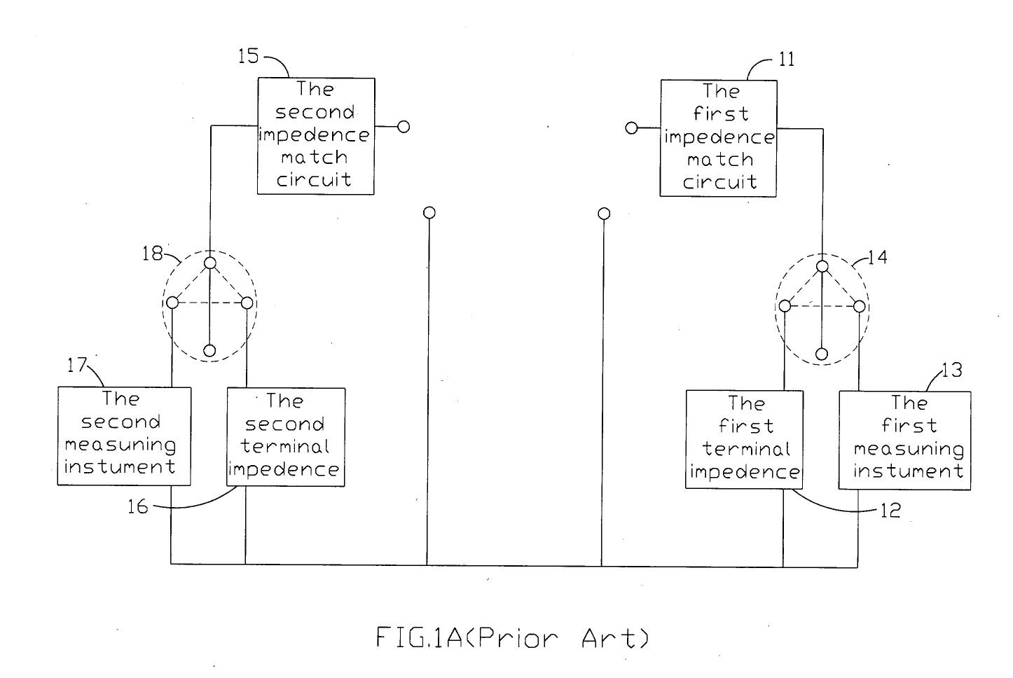

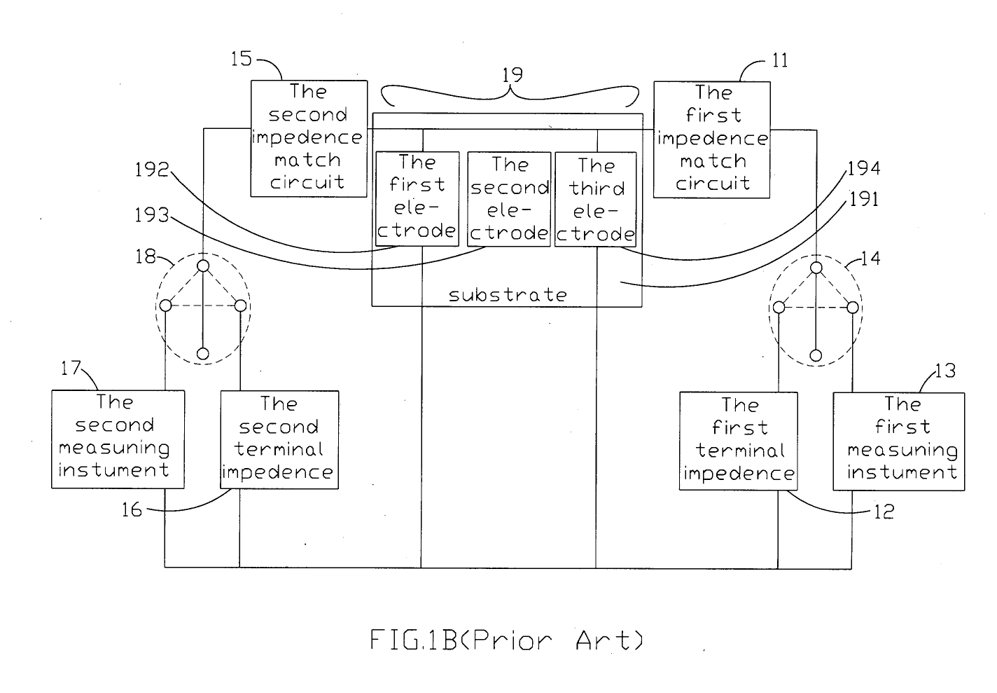

One preferred embodiment of the invention is a measurement circuit of a three poles monolithic quartz crystal filter. As is shown in FIGS. 1A and 1B, comprising: the first impedance match circuit 11, the first terminal impedance 12, the first measuring instrument 13, the first switch 14, the second impedance match circuit 15, the second terminal impedance 16, the second measuring instrument 17, and the second switch 18. Obviously, the preferred embodiment is located respectively on the two sides of the three poles monolithic quartz crystal filter 19, which is fundamentally composed of the first electrode 192 located on the substrate 191, the second electrode 193, and the third electrode 194.

As is shown in the drawings, the first in-and-output pole of the first impedance match circuit 11 is electrically coupled with the first in-and-output pole of the third electrode 194 of the three poles monolithic quartz crystal filter 19; the first in-and-output pole of the first terminal impedance 12 is electrically coupled with the second in-and-output pole of the third electrode 194; the first in-and-output pole of the first measuring instrument 13 is electrically coupled with the second in-and-output pole of the third electrode 194; the first pole of the first switch 14 is electrically coupled with the second in-and-output pole of the first impedance match circuit 11, and the second pole of the first switch 14 switches between the second in-and-output pole of the first terminal impedance 12 and the second in-and-output pole of the first measuring instrument 13. Symmetrically, the first in-and-output pole of the second impedance match circuit 15 is electrically coupled with the first in-and-output pole of the first electrode 192 of the three poles monolithic quartz crystal filter 19; the first in-and-output pole of the second terminal impedance 16 is electrically coupled with the second in-and-output pole of the first electrode 192, and the first in-and-output pole of the second terminal impedance 16 is electrically coupled with the first in-and-output pole of the first terminal impedance 12; the first in-and-output pole of the second measuring instrument 17 is electrically coupled with the second in-and-output pole of the first electrode 192; and one end of the second switch 18 is electrically coupled with the second in-and-output pole of the second impedance match circuit 15, with the other end of it switching between the second in-and-output pole of the second terminal impedance 15 and the second in-and-output pole of the second measuring instrument 17.

Obviously, one of the main features of the preferred embodiment is applying the first switch 14 and the second switch 18. Through switching the switches 14 and 18, the two electrodes 192 and 194 on the two sides of the three poles monolithic quartz crystal filter 19 can be electrically coupled with the terminal impedance 13/17 or with the measuring instrument 14/18. Therefore, the transparent and reflective response of the three poles monolithic quartz crystal filter 19 can be acquired through proper adjustment of the terminal impedance 13/17 and the impedance match circuit 11/15.

For example, when the two switches 192 and 194 link the two sides of the three poles monolithic quartz crystal filter 19 respectively to the measuring instrument 14/18, the Fo and BW are acquired. For example, when the two switches 192 and 194 link one end of the three poles monolithic quartz crystal filter 19 to the measuring instrument 14/18 and the other end of it to the terminal impedance 17/13, the 3-poles filter 19 is simplified into two 2-poles filters, and thus the A-sym of these two 2-poles filters can be acquired, from which the A-sym of the 3-poles filter 19 can be figured out.

In other words, through switching the switches 14/18, the Fo and BW, or the A-sym of the three poles monolithic quartz crystal filter 19 can be measured with this preferred embodiment. That is to say, with this preferred embodiment, the same measuring circuit can be used to measure the Fo, BW, and A-sym of the three poles monolithic quartz crystal filter 19, which is different from the prior technology in which two measuring circuits have to be used in order to measure the Fo, BW, and A-sym of the three poles monolithic quartz crystal filter 19.

In the preferred embodiment, the first impedance match circuit 11 is used mainly for providing the first match impedance, which is provided for the match impedance that is needed by the first measuring instrument 14 when the first measuring instrument 14 and the second measuring instrument 18 are used to measure the Fo and BW of the three poles monolithic quartz crystal filter 19. It is the same with the second impedance match circuit 15, which is provided for the second match impedance, necessary to the second measuring instrument 18 when the second measuring instrument 18 and the first measuring instrument 14 are used to measure the Fo and BW of the three poles monolithic quartz crystal filter 19.

In the preferred embodiment, the first terminal impedance 12 is mainly used to offset the static capacitance of the third electrode 194 to make it incapable of functioning when the first terminal impedance 12 and the third electrode 194 are electrically coupled. Generally speaking, the first terminal impedance 12 can be capacitance or inductance resistance, the capacitance of the capacitor equaling the static capacitance of the third electrode 194 but having different direction from the static capacitance of the third electrode 194. Similarly, the second terminal impedance 16 is mainly used to offset the static capacitance of the first electrode 192 to make it incapable of functioning when the second terminal impedance 16 and the first electrode 192 are electrically coupled. Generally speaking, the second terminal impedance 16 can be capacitance or inductance resistance, the capacitance of the capacitor equaling the static capacitance of the first electrode 192 but having different direction from the static capacitance of the first electrode 192. The advantage is that the function of the third electrode 194 and/or the first electrode 192 can be eliminated only by the out-linking first terminal impedance 12 and/or the second terminal impedance 16 without changing the structure of the three poles monolithic quartz crystal filter 19, and therefore provides an un-destructive measuring method.

In the preferred embodiment, the first measuring instrument 14 can be a prior instrument measuring the Fo and BW of a three poles monolithic quartz crystal filter, and the second measuring instrument 18 can also be a prior instrument measuring the Fo and BW of a three poles monolithic quartz crystal filter.

In the preferred embodiment, since the two switches 14/18 have to be able to switch the statuses of linking, the first switch 14 and the second switch 18 can both be one-to-two switches. Of course, in order to heighten the frequency of reaction, the electronic switches such as transistor and PIN diode can also be used.

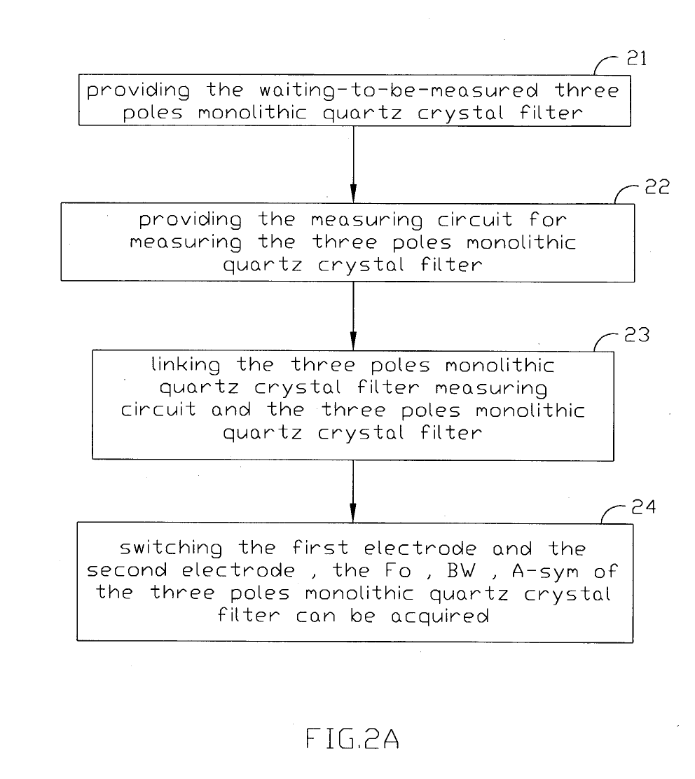

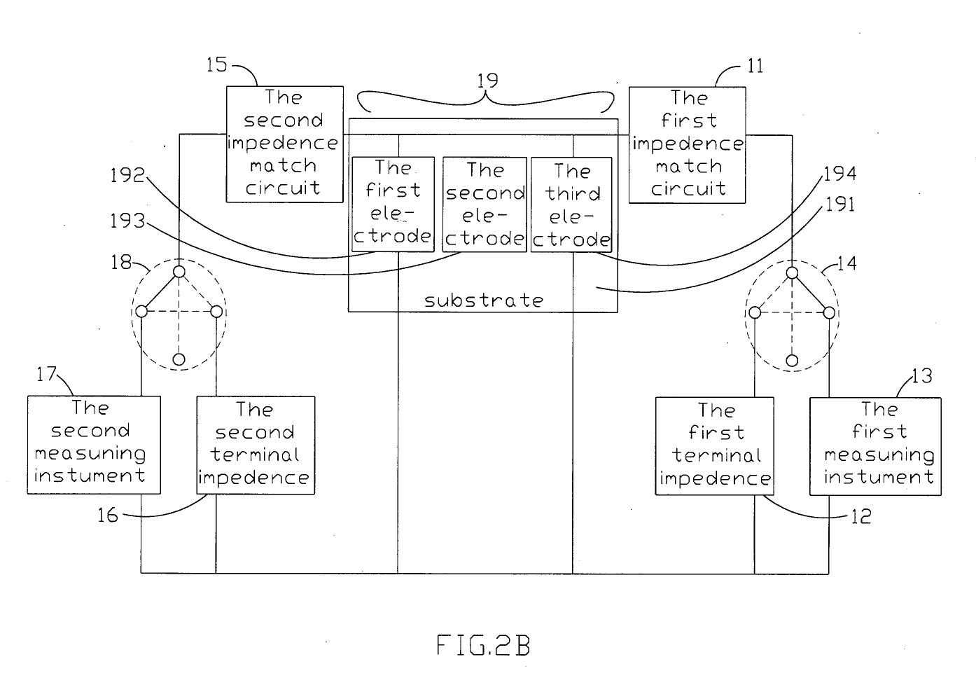

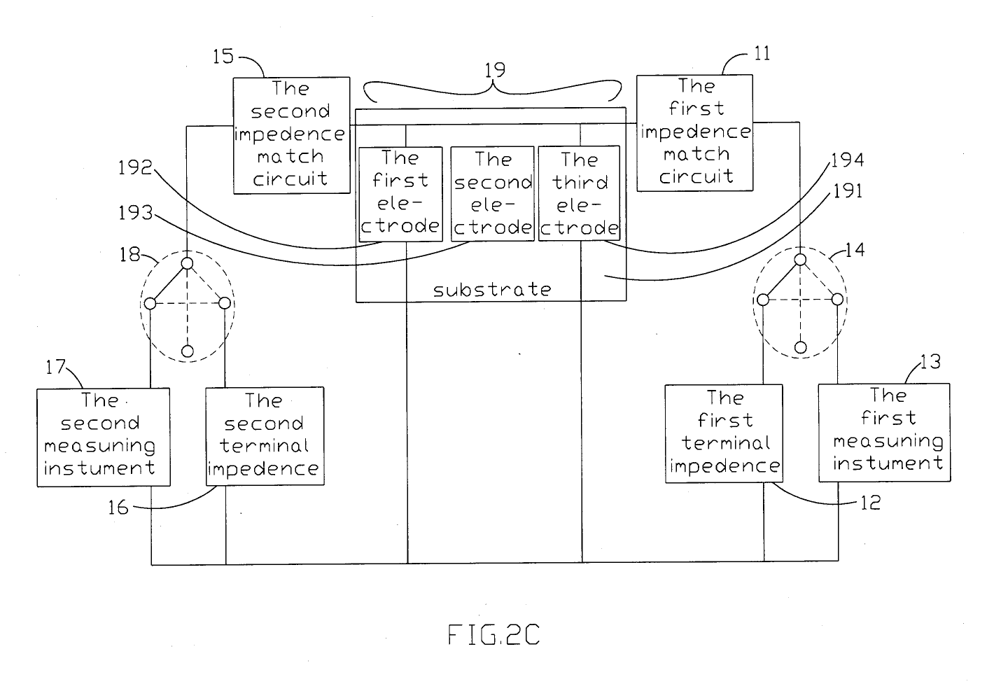

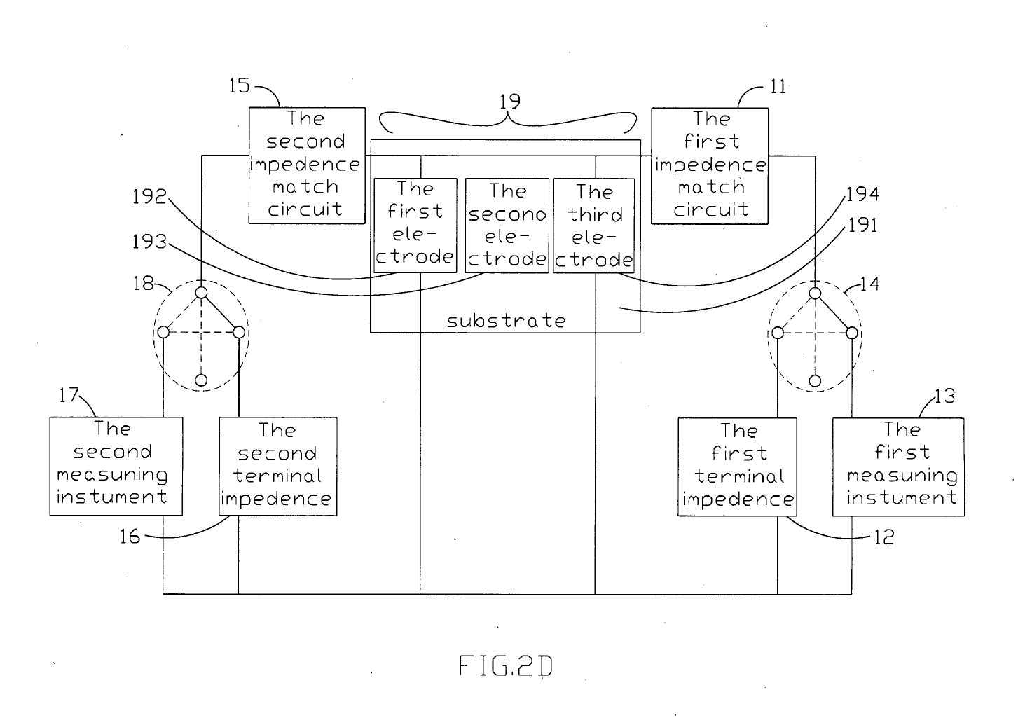

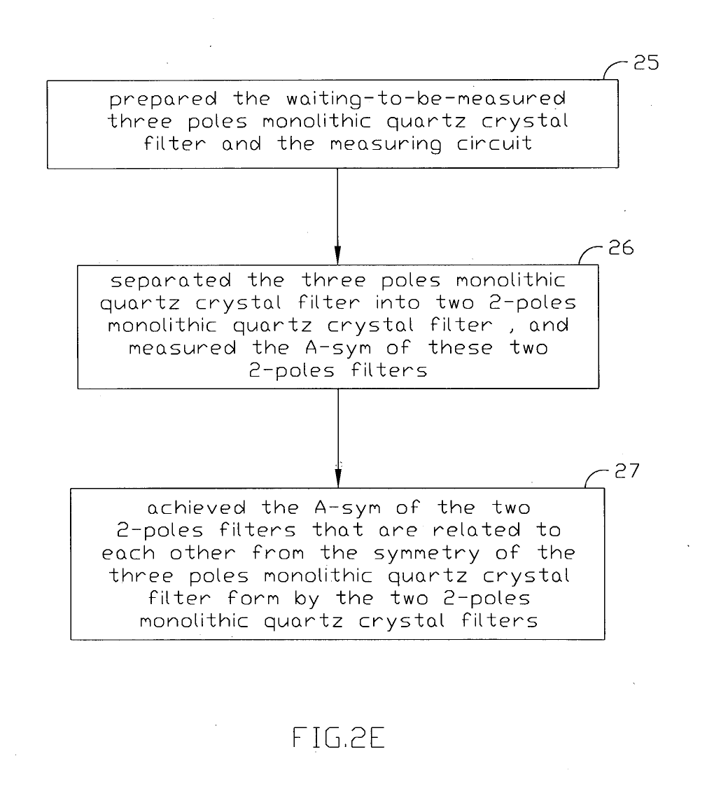

Another preferred embodiment of the invention is the method of measuring the three poles monolithic quartz crystal filter. As FIG. 2A shows, the following fundamental steps are comprised:

As is shown in the sample square 21, the waiting-to-be-measured three poles monolithic quartz crystal filter is provided.

In this sample, the three poles monolithic quartz crystal filter has on it the first, the second, and the third electrodes orderly in line, the source and drain of the second electrode are in short-circuits, but the source and drain of the first and the second electrodes are separated from each other.

As is shown in the measuring instrument square 22, the measuring circuit for measuring the three poles monolithic quartz crystal filter is provided. This measuring circuit is the measuring circuit of the three poles monolithic quartz crystal filter in the previous preferred embodiment.

This measuring instrument comprises essentially of the first impedance match circuit, the first terminal impedance, the first measuring instrument, the first switch, the second impedance match circuit, the second terminal impedance, the second measuring instrument, and the second switch, with the first in-and-output pole of the first switch being electrically coupled with the first in-and-output pole of the first impedance match circuit, the second in-and-output pole of the first switch switching between the first in-and-output pole of the first terminal impedance and the first in-and-output pole of the first measuring instrument, the first in-and-output pole of the second switch being electrically coupled with the first in-and-output pole of the second impedance match circuit, the second in-and-output pole if the second switch switching between the first in-and-output pole of the second terminal impedance and the first in-and-output pole of the second measuring instrument, and the first in-and-output pole of the first terminal impedance, the first in-and-output pole of the second terminal impedance, the first in-and-output pole of the first measuring instrument, and the first in-and-output pole of the second measuring instrument being electrically coupled among one another.

As is shown in the preparation square 23 the three poles monolithic quartz crystal filter measuring circuit and the three poles monolithic quartz crystal filter are linked.

Here, the second in-and-output pole of the first impedance match circuit is electrically coupled with the first in-and-output pole of the third electrode, the second in-and-output pole of the second terminal impedance is electrically coupled with the first in-and-output pole of the third electrode, the second in-and-output pole of the first measuring instrument is electrically coupled with the second in-and-output pole of the third electrode, the second in-and-output pole of the second measuring instrument is electrically coupled with the second in-and-output pole of the first electrode, the second in-and-output pole of the first impedance match circuit is electrically coupled with both the second in-and-output pole of the third electrode of the three poles monolithic quartz crystal filter and the second in-and-output pole of the first electrode of the filter, and the second in-and-output pole of the second impedance match circuit is electrically coupled with both the second in-and-output pole of the first electrode of the three poles monolithic quartz crystal filter and the second in-and-output pole of the third electrode of the filter.

As is shown in the switching process square 24, through switching the first electrode and the second electrode, the Fo, BW, and A-sym of the three poles monolithic quartz crystal filter can be acquired.

As is shown in FIG. 2B, when the Fo and BW of the three poles monolithic quartz crystal filter are being measured by the first measuring instrument 13 and the second measuring instrument 17, the first switch 14 is being electrically coupled with the first impedance match circuit 11 and the first measuring instrument 13, the second switch 18 is being electrically coupled with the second impedance match circuit 15 and the second measuring instrument 18. What is mentionable is that at this time neither the first switch 14 and the first terminal impedance 12 nor the second switch 18 and the second terminal impedance 16 are linked with each other.

Since measuring the Fo and BW of the three poles monolithic quartz crystal filter 19 from the two sides of it with two measuring instruments is of prior technology, for example, the prior measuring instrument HP ES 100A designed by HP that can measure the Fo and BW of the three poles monolithic quartz crystal filter, no further details will be offered here. In fact, as is said above, the main feature of the invention is to integrate the measurements of Fo, BW, and A-sym of the three poles monolithic quartz crystal filter 19, and to solve the problem of measuring the A-sym of the 3-poles filter in the prior technology.

Here, the A-sym of the three poles monolithic quartz crystal filter 19 is being measured and acquired through the following steps:

(a) As is shown in FIG. 2C, the first switch 14 is electrically coupled with the first impedance match circuit and the first terminal impedance 12, and the second switch 18 is electrically coupled with the second impedance match circuit 15 and the second measuring instrument 18 at this time the first switch 14 and the first measuring instrument 11 become open-circuit and the second switch 18 and the second terminal impedance 16 also become open-circuit.

(b) Then, the A-sym of the equal-effect 2-poles monolithic quartz crystal filter, formed by the first and the second electrodes, is measured by the first measuring instrument 14 and the second measuring instrument 18;

(c) As is shown in FIG. 2D, the second switch 18 is electrically coupled with the second impedance match circuit 15 and the second terminal impedance 16, and the first switch 14 is electrically coupled with the first impedance match circuit 11 and the first measuring instrument 13 at this time the second switch 18 and the second measuring instrument 17 become open-circuit and the first switch 14 and the first terminal impedance 11 also become off-circuit.

(d) Then, the A-sym of the equal-effect 2-poles monolithic quartz crystal filter, formed by the second and the third electrodes, is measured by the first measuring instrument 14 and the second measuring instrument 18.

(e) Finally, with the A-sym of the equal-effect 2-poles monolithic quartz crystal filter formed by the first and the second electrodes and the A-sym of the equal-effect 2-poles monolithic quartz crystal filter formed by the second and the third electrodes, the A-sym of the three poles monolithic quartz crystal filter 19 can be acquired. Here the conventional two-pole short-circuits bandwidth theorem can be used to figure out the A-sym of the three poles monolithic quartz crystal filter 19.

The process of the steps above can indicated summarily by the process showed in FIG. 2E: first, as in the preparation square25, the waiting-to-be-measured three poles monolithic quartz crystal filter and the measuring circuit are prepared; as in the stage-by-stage measurement square 26, the waiting-to-be-measured three poles monolithic quartz crystal filter is separated into two 2-poles monolithic quartz crystal filter, and the A-sym of these two 2-poles filters are measured; as in the square 27, the symmetry of the three poles monolithic quartz crystal filter formed by the two 2-poles monolithic quartz crystal filters is achieved from the A-sym of the two 2-poles filters that are related to each other.

What needs to be explained is that the order of the step (a)(b) and then the step (c)(d) can be reversed. That is to say that whether the A-sym of the equal-effect of the 2-poles monolithic quartz crystal filter of the first electrode and the second electrode is measured first or the A-sym of the 2-poles monolithic quartz crystal filter of the second electrode and the third electrode is measured first is not important to the embodiment.

The first terminal impedance 12 is usually adjusted to be able to offset the static capacitance of the third electrode when the first terminal impedance 12 is electrically coupled with the third electrode in the embodiment. For example, the first terminal impedance 12 can be a capacitor, the capacitance of which equals the static capacitance of the third electrode but the direction of which is opposite to that of the static capacitance of the third electrode. Of course, the first terminal impedance 12 can also be inductance resistance.

The second terminal impedance 16 is usually adjusted to be able to offset the static capacitance of the first electrode when the second terminal impedance 16 is electrically coupled with the first electrode in the embodiment. For example, the second terminal impedance 16 can be a capacitor, the capacitance of which equals the static capacitance of the first electrode but the direction of which is opposite to that of the static capacitance of the first electrode. Of course, the second terminal impedance 12 can also be inductance resistance.

The first impedance match circuit 11 in the embodiment is usually adjusted to provide the match impedance needed by the first measuring instrument 14 when the Fo and BW of the three poles monolithic quartz crystal filter 19 are measured by the first measuring instrument 14 and the second measuring instrument 18. The second impedance match circuit 15 is also adjusted to provide the match impedance needed by the second measuring instrument 18 when the Fo and BW of the three poles monolithic quartz crystal filter 19 are measured by the first measuring instrument 14 and the second measuring instrument 18.

What is said above is only a preferred embodiment of the invention, which is not to be used to limit the claims of the invention; any changes of equal effect or modifications that do not depart from the essence displayed by the invention should be limited in what is claimed in the following.

1. A three poles monolithic quartz crystal filter, comprising:
a first impedance match circuit, the first in-and-output pole of the said impedance match circuit being electrically coupled with a first in-and-output pole of a third electrode of a three poles monolithic quartz crystal filter;
a first terminal impedance, a first in-and-output pole of the said first terminal impedance being electrically coupled with a second in-and-output pole of the said third electrode;
a first measuring instrument, a first in-and-output pole of the said first measuring instrument being electrically coupled with the said second in-and-output pole of the said third electrode;
a first switch, a first end of the said first switch being electrically coupled with the second in-and-output pole of the said first impedance match circuit, and a second end of the said first switch switching between a second in-and-output pole of the said first terminal impedance and a second in-and-output pole of the said first measuring instrument;
a second impedance match circuit, a first in-and-output pole of the said impedance match circuit being electrically coupled with a first in-and-output pole of a first electrode of the said three poles monolithic quartz crystal filter;
a second terminal impedance, a first in-and-output pole of the said second terminal impedance being electrically coupled with a second in-and-output pole of the said first electrode, and the said first in-and-output pole of the said second terminal impedance being electrically coupled with the said first in-and-output pole of the said first terminal impedance;
a second measuring instrument, a first in-and-output pole of the said second measuring instrument being electrically coupled with the said second in-and-output pole of the said first electrode;
a second switch, one end of the said second switch being electrically coupled with a second in-and-output pole of the said second impedance match circuit, and the other end of the said second switch switching between a second in-and-output pole of the said second terminal impedance and a second in-and-output pole of the said second measuring instrument.

2. The measuring circuit according to claim 1, wherein the said first impedance match circuit provides a first match impedance, the said first match impedance being the match impedance needed by the said first measuring instrument when the said first measuring instrument and the said second measuring instrument measure the Fo and BW of the said three poles monolithic quartz crystal filter

3. The measuring circuit according to claim 1, wherein the said second impedance match circuit provides a second match impedance, the said second match impedance being the match impedance needed by the said second measuring instrument when the said first measuring instrument and the said second measuring instrument measure the Fo and BW of the said three poles monolithic quartz crystal filter.

4. The measuring circuit according to claim 1, wherein the said first terminal impedance offsets the static capacitance of the said third electrode when the said first terminal impedance is electrically coupled with the said third electrode.

5. The measuring circuit according to claim 1, wherein the said first terminal impedance is a capacitor, the capacitance of the said capacitor equaling the static capacitance of the said third electrode and the direction of the said capacitor being opposite to that of the static capacitance of the said third electrode.

6. The measuring circuit according to claim 1, wherein the said second terminal impedance offsets the static capacitance of the said first electrode when the said second terminal impedance is electrically coupled with the said first electrode.

7. The measuring circuit according to claim 1, wherein the said second terminal impedance is a capacitor, the capacitance of the said capacitor equaling the static capacitance of the said first electrode and the direction of the said capacitor being opposite to that of the static capacitance of the said first electrode.

8. The measuring circuit according to claim 1, wherein the said first measuring instrument is a prior measuring instrument of measuring the Fo and BW of the three poles monolithic quartz crystal filter.

9. The measuring circuit according to claim 1, wherein the said second measuring instrument is a prior measuring instrument of measuring the Fo and BW of the three poles monolithic quartz crystal filter.

10. The measuring circuit according to claim 1, wherein the said first switch is a one-to-two switch.

11. The measuring circuit according to claim 1, wherein the said second switch is a one-to-two switch.

12. A method of measuring the three poles monolithic quartz crystal filter, comprising:
providing a three poles monolithic quartz crystal filter, the said three poles monolithic quartz crystal filter having on it a first, a second, and a third electrode orderly in line, the source and drain of the said second electrode being in short circuits, but the source and the drain of the said first electrode and the said second electrode being all separated from each other;
providing a three poles monolithic quartz crystal filter measuring circuit, the said three poles monolithic quartz crystal filter comprising a first impedance match circuit, a first terminal impedance, a first measuring instrument, a first switch, a second impedance match circuit, a second terminal impedance, a second measuring instrument, and a second switch, a first in-and-output pole of the said first switch being electrically coupled with a first in-and-output pole of the said first impedance match circuit, a second in-and-output pole of the said first switch switching between a first in-and-output pole of the said first terminal impedance and a first in-and-output pole of the said first measuring instrument, a first in-and-output pole of the said second switch being electrically coupled with a first in-and-output pole of the said second impedance match circuit, a second in-and-output pole of the said second switch switching between a first in-and-output pole of the said second terminal impedance and a first in-and-output pole of the said second measuring instrument, and the said first in-and-output pole of the said first terminal impedance, the said first in-and-output pole of the said second terminal impedance, the said first in-and-output pole of the said first measuring instrument, and the said first in-and-output pole of the said second measuring instrument being electrically coupled with each other;
linking the three poles monolithic quartz crystal filter and the three poles monolithic quartz crystal filter measuring circuit, making a second in-and-output pole of the said first impedance match circuit electrically coupled with a first in-and-output pole of the said third electrode, a second in-and-output pole of the said second terminal impedance electrically coupled with a first in-and-output pole of the said third electrode, the said second in-and-output pole of the said first measuring instrument electrically coupled with the said second in-and-output pole of the said third electrode, the said second in-and-output pole of the said second measuring instrument electrically coupled with the said second in-and-output pole of the said first electrode, the said second in-and-output pole of the said first impedance match circuit electrically coupled with both the said second in-and-output pole of the said third electrode of the said three poles monolithic quartz crystal filter and the said second in-and-output pole of the said first electrode of the said three poles monolithic quartz crystal filter, and the said second in-and-output pole of the said second impedance match circuit electrically coupled with both the said second in-and-output pole of the said first electrode of the said three poles monolithic quartz crystal filter and the said second in-and-output pole of the said third electrode of the said three poles monolithic quartz crystal filter; and
measuring the Fo, BW, and A-sym of the said three poles monolithic quartz crystal filter by switching the said first electrode and the said second electrode.

13. The measuring method according to claim 12, the Fo and BW of the said three poles monolithic quartz crystal filter are measured by the said first measuring instrument, which is electrically coupled with the said first switch and the said first impedance match circuit, and the said second measuring instrument, which is electrically coupled with the said second switch and the said second impedance match circuit.

14. The measuring method according to claim 13, the said first switch and the said first terminal impedance are open-circuit each other and the said second switch and the said second terminal impedance are open-circuit each other

15. The measuring method according to claim 12, the measurement of the A-sym of the said three poles monolithic quartz crystal filter are accomplished through the following steps:
(a) the said first switch being electrically coupled with the said first impedance match circuit and the said first terminal impedance, the said second switch being electrically coupled with the said second impedance match circuit and the said second measuring instrument, at this time the said first switch and the said first measuring instrument becoming open-circuit, and the said second switch and the said second terminal impedance also becoming open-circuit;
(b) measuring the A-sym of the said first electrode and the said second electrode with the said first measuring instrument and the said second measuring instrument;
(c) the said second switch being electrically coupled with the said second impedance match circuit and the said second terminal impedance, the said first switch being electrically coupled with the said first impedance match circuit and the said first measuring instrument, at this time the said second switch and the said second measuring instrument becoming open-circuit, and the said first switch and the said first terminal impedance also becoming open-circuit;
(d) measuring the A-sym of the said second electrode and the said third electrode with the said first measuring instrument and the said second measuring instrument; and
(e) achieving the A-sym of the said three poles monolithic quartz crystal filter from the A-sym of the said first electrode and the said second electrode and the A-sym of the said second electrode and the said third electrode.

16. The measuring method according to claim 15, the order of step (a)(b) and then step (c)(d) said above can be reversed.

17. The measuring method according to claim 15, the step (e) said above applies the conventional two-pole short-circuits bandwidth theorem in order to achieve the A-sym of the said three poles monolithic quartz crystal filter.

18. The measuring method according to claim 12, the first terminal impedance is adjusted to be able to offset the static capacitance of the said third electrode when the said first terminal impedance is electrically coupled with the said third electrode.

19. The measuring method according to claim 12, the said first terminal impedance is a capacitor, the capacitance of which equals the static capacitance of the said third electrode, and the direction of which is opposite to that of the static capacitor of the said third electrode.

20. The measuring method according to claim 12, the second terminal impedance is adjusted to be able to offset the static capacitance of the said first electrode when the said second terminal impedance is electrically coupled with the said first electrode.

21. The measuring method according to claim 12, the said second terminal impedance is a capacitor, the capacitance of which equals the static capacitance of the said first electrode, and the direction of which is opposite to that of the static capacitor of the said first electrode.

22. The measuring method according to claim 12, the first impedance match circuit is adjusted to be able to provide the match impedance needed by the said first measuring instrument when the Fo and BW of the said three poles monolithic quartz crystal filter are measured by the said first measuring instrument and the said second measuring instrument.

23. The measuring method according to claim 12, the second impedance match circuit is adjusted to be able to provide the match impedance needed by the said second measuring instrument when the Fo and BW of the said three poles monolithic quartz crystal filter are measured by the said first measuring instrument and the said second measuring instrument.

24. The measuring method according to claim 12, the said first measuring instrument and the said second measuring instrument are conventional instrument of measuring the Fo and BW of the three poles monolithic quartz crystal filter.

25. The measuring method according to claim 12, the said first switch and the said second switch are conventional one-to-two switches.
